(19) United States
(12) Patent Application Publication
(10) Pub. No.: US 2024/0276798 A1
(43) Pub. Date: Aug. 15, 2024

(54) DISPLAY SUBSTRATE AND DISPLAY DEVICE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Biao LIU, Beijing (CN); Tinghua SHANG, Beijing (CN); Yixuan LONG, Beijing (CN); Jiaxing CHEN, Beijing (CN); Zuoji NIU, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 18/022,006

(22) PCT Filed: May 7, 2022
(86) PCT No.: PCT/CN2022/091459

§ 371 Date: Feb. 17, 2023

(51) Int. Cl. H10K 59/126; H10K 59/122; H10K 59/123; H10K 59/35; H10K 59/80

(52) U.S. Cl. CPC H10K 59/126; H10K 59/122; H10K 59/123; H10K 59/353; H10K 59/80515

(57) ABSTRACT

A display substrate and a display device are provided. The display substrate has a display side and includes a base substrate, a drive circuit layer, a first electrode layer, and a pixel definition layer. The drive circuit layer includes a plurality of first gaps to allow light from the display side to transmit therethrough. The first electrode layer includes a plurality of first electrode patterns and a plurality of light-blocking patterns. The pixel definition layer includes a plurality of sub-pixel openings exposing the plurality of first electrode patterns, respectively. In a direction perpendicular to the base substrate, at least a portion of the plurality of light-blocking patterns do not overlap with the plurality of sub-pixel openings, and correspond to and at least partially overlapped with at least a portion of the plurality of first gaps, respectively.

### TECHNICAL FIELD

Embodiments of the present disclosure relate to a display substrate and a display device.

### BACKGROUND

An Organic Light Emitting Diode (OLED) display device has many advantages, such as self-luminescence, high contrast, high definition, wide viewing angle, low power consumption, fast response speed and low manufacturing cost, etc. It has become one of the important development directions of the new generation of display devices. Accordingly, it has attracted more and more attention.

Currently, the display device usually has many functions, such as fingerprint recognition. In this case, the structure of the display device can be adjusted correspondingly for the functions.

### SUMMARY

At least one embodiment of the disclosure provides a display substrate, having a display side and comprising: a base substrate, a drive circuit layer, disposed on the base substrate, comprising a plurality of first gaps, wherein the plurality of first gaps allow light from the display side to transmit therethrough, a first electrode layer, disposed on a side of the drive circuit layer away from the base substrate and comprising a plurality of first electrode patterns and a plurality of light-blocking patterns, a pixel definition layer, disposed on a side of the first electrode layer away from the base substrate and comprising a plurality of sub-pixel openings, wherein the plurality of sub-pixel openings expose the plurality of first electrode patterns, respectively, wherein, in a direction perpendicular to the base substrate, at least a portion of the plurality of light-blocking patterns do not overlap with the plurality of sub-pixel openings, the at least a portion of the plurality of light-blocking patterns correspond to and at least partially overlapped with at least a portion of the plurality of first gaps, respectively, so as to at least partially block light from the display side.

For example, in the display substrate provided by at least one embodiment of the disclosure, a width of the plurality of first gaps is less than or equal to 4.0 micrometers.

For example, in the display substrate provided by at least one embodiment of the disclosure, a distance of the plurality of first gaps from a center of the plurality of sub-pixel openings is less than 33 micrometers.

For example, in the display substrate provided by at least one embodiment of the disclosure, the at least a portion of the plurality of light-blocking patterns are integrally connected to the plurality of first electrode patterns, respectively.

For example, in the display substrate provided by at least one embodiment of the disclosure, each of the plurality of first electrode patterns comprises a main part and a connection part, and a plane shape of the main part is polygon or a shape with arc edge, and a plane shape of the plurality of light-blocking patterns is polygon.

For example, in the display substrate provided by at least one embodiment of the disclosure, the display substrate comprises a plurality of sub-pixels, each of the plurality of sub-pixels comprises a light emitting device, and the plurality of first electrode patterns are used as anodes of the light-emitting devices of the plurality of sub-pixels, respectively.

For example, in the display substrate provided by at least one embodiment of the disclosure, the plurality of sub-pixels comprises red sub-pixels, green sub-pixels and blue sub-pixels, wherein a plane shape of the main part of the first electrode pattern of the light emitting device of each of the red sub-pixels is hexagon, and a shape of the light-blocking pattern integrally connected with the first electrode pattern of the light emitting device of each of the red sub-pixel is triangle.

For example, in the display substrate provided by at least one embodiment of the disclosure, a number of light-blocking patterns integrally connected with the first electrode pattern of the light emitting device of each of the red sub-pixel is two, and the two light-blocking patterns integrally connected with the first electrode pattern of the light emitting device of each of the red sub-pixels are arranged symmetrically.

For example, in the display substrate provided by at least one embodiment of the disclosure, a plane shape of the main part of the first electrode pattern of the light emitting device of each of the blue sub-pixels is hexagon, and a shape of the light-blocking patterns integrally connected with the first electrode pattern of the light emitting device of each of the blue sub-pixels is triangle or rectangular.

For example, in the display substrate provided by at least one embodiment of the disclosure, a number of light-blocking patterns integrally connected with the first electrode pattern of the light emitting device of each of the blue sub-pixels is three, and the three light-blocking patterns integrally connected with the first electrode pattern of the light emitting device of each of the blue sub-pixels are integrally connected with three edges of the first electrode pattern of the light emitting device of each of the blue sub-pixels.

For example, in the display substrate provided by at least one embodiment of the disclosure, a plane shape of the main part of the first electrode pattern of the light emitting device of each of the green sub-pixels is pentagon, and a shape of the light-blocking patterns integrally connected with the first electrode pattern of the light emitting device of each of the green sub-pixels is rectangular.

For example, in the display substrate provided by at least one embodiment of the disclosure, a number of light-blocking patterns integrally connected with the first electrode pattern of the light emitting device of each of the green sub-pixels is one or two, and the one or two light-blocking patterns integrally connected with the first electrode pattern of the light emitting device of each of the green sub-pixels are integrally connected with one edge or two edges of the first electrode pattern of the light emitting device of each of the green sub-pixels, respectively.

For example, in the display substrate provided by at least one embodiment of the disclosure, for the sub-pixel opening and the first electrode pattern corresponding to each other, a shape of the sub-pixel opening is the same as a shape of the main part of the first electrode pattern, a first orthographic projection of the sub-pixel opening on the base substrate is within a second orthographic projection of the main part of the first electrode pattern on the base substrate, and a minimum distance between an edge of the first orthographic projection and an edge of the second orthographic projection is from 1.5 micrometers to 3.5 micrometers.

For example, in the display substrate provided by at least one embodiment of the disclosure, the light emitting devices of the red sub-pixels and the blue sub-pixels are located in same rows, the light emitting devices of the green sub-pixels of are substantially located in same rows, and the rows where the light emitting devices of the red sub-pixel and the blue sub-pixel are located and the rows where the light emitting devices of the green sub-pixels are located are arranged alternately.

For example, in the display substrate provided by at least one embodiment of the disclosure, the drive circuit layer further comprises a plurality of second gaps, wherein the plurality of second gaps allow light from the display side to transmit therethrough, in the direction perpendicular to the base substrate, the plurality of second gaps do not overlap with the plurality of first electrode patterns and the plurality of light-blocking patterns.

For example, in the display substrate provided by at least one embodiment of the disclosure, a distance of the plurality of second gaps from a center of the plurality of sub-pixel openings is greater than 33 micrometers.

For example, in the display substrate provided by at least one embodiment of the disclosure, an orthographic projection of each of the plurality of second gaps on the base substrate is located between an orthographic projection of light emitting control signal line on the base substrate and an orthographic projection of a reset voltage line adjacent to the light emitting control signal line on the base substrate.

For example, in the display substrate provided by at least one embodiment of the disclosure, an orthographic projection of each of at least a portion of the plurality of second gaps on the base substrate is located between an orthographic projection of a light emitting control signal line for a blue sub-pixel on the base substrate and an orthographic projection of a reset voltage line for a red sub-pixel on the base substrate, wherein the red sub-pixel is located in a row next to a row where the blue sub-pixel is located and is adjacent to the blue sub-pixel; and/or an orthographic projection of each of at least a portion of the plurality of second gaps on the base substrate is located between an orthographic projection of a light emitting control signal line for a red sub-pixel on the base substrate and an orthographic projection of a reset voltage line for the blue sub-pixel on the base substrate, wherein the blue sub-pixel is located in a row next to a row where the red sub-pixel is located and is adjacent to the red sub-pixel.

For example, in the display substrate provided by at least one embodiment of the disclosure, a width of each of at least a portion of the plurality of second gaps is greater than 4.0 micrometers.

For example, in the display substrate provided by at least one embodiment of the disclosure, the drive circuit layer comprises, a plurality of pixel drive circuits, and a first planarization layer, disposed on a side of the plurality of pixel drive circuits away from the base substrate and comprising a plurality of firs via holes, wherein the plurality of first via holes expose output terminals of the plurality of pixel drive circuits, respectively, wherein the first electrode layer is disposed on a side of the first planarization layer away from the base substrate, and the plurality of first electrode patterns are connected with the output terminals of the plurality of pixel drive circuits through the plurality of first via holes, respectively, the display substrate further comprises a spacer layer disposed on a side of the pixel definition layer away from the base substrate, and the spacer layer comprises a plurality of spacers; in the direction perpendicular to the base substrate, the plurality of spacers do not overlap with the plurality of first via holes.

For example, in the display substrate provided by at least one embodiment of the disclosure, in a direction parallel to the base substrate, a minimum distance between the plurality of spacers and the plurality of first via holes is greater than 2.0 micrometers.

For example, in the display substrate provided by at least one embodiment of the disclosure, the drive circuit layer comprises, a plurality of pixel drive circuits, a first planarization layer, disposed on a side of the plurality of pixel drive circuits away from the base substrate and comprising a plurality of firs via holes, wherein the plurality of first via holes expose output terminals of the plurality of pixel drive circuits, respectively, a connection electrode layer, disposed on a side of the first planarization layer away from the base substrate and comprising a plurality of connection electrodes, wherein the plurality of connection electrodes are electrically connected with the output terminals of the plurality of pixel drive circuits through the first via holes, respectively, and a second planarization layer, disposed on a side of the connection electrode layer away from the base substrate and comprising a plurality of second via holes, wherein the plurality of second via holes expose the plurality of connection electrodes, respectively; wherein the first electrode layer is disposed on a side of the second planarization layer away from the base substrate, and the plurality of first electrode patterns are electrically connected with the plurality of connection electrodes, respectively, the display substrate further comprises a spacer layer disposed on a side of the pixel definition layer away from the base substrate, and the spacer layer comprises a plurality of spacers, in the direction perpendicular to the base substrate, the plurality of spacers do not overlap with the plurality of second via holes.

For example, in the display substrate provided by at least one embodiment of the disclosure, in a direction parallel to the base substrate, a minimum distance between the plurality of spaces and the plurality of second via holes is greater than 2.0 micrometers.

For example, in the display substrate provided by at least one embodiment of the disclosure, in the direction perpendicular to the base substrate, a height of each of the plurality of spacers is from 1.8 micrometers to 2.4 micrometers.

For example, in the display substrate provided by at least one embodiment of the disclosure, in a direction perpendicular to the base substrate, the plurality of pixel drive circuits at least partially overlap with the plurality of pixel openings.

At least one embodiment of the disclosure provides a display device, comprising the display substrate provided by any embodiments as mentioned above.

### BRIEF DESCRIPTION OF DRAWINGS

In order to clearly illustrate the technical solution of the embodiments of the present disclosure, the drawings of the embodiments will be briefly described in the following. It is obvious that the described drawings are only related to some embodiments of the present disclosure and thus are not limitative of the present disclosure.

FIG. 1 is a partial plane schematic diagram of a display substrate provided by at least one embodiment of the disclosure;

FIG. 2 is a partial plane schematic diagram of a first electrode layer of a display substrate provided by at least one embodiment of the disclosure;

FIG. 3 is a partial plane schematical diagram of a drive circuit layer of a display substrate provided by at least one embodiment of the disclosure;

FIG. 4 is a partial section schematic diagram of a sub-pixel of a display substrate provided by at least one embodiment of the disclosure;

FIG. 5 is a partial plane schematic diagram in which a first electrode layer is stacked on a pixel definition layer of the display substrate provided by at least one embodiment of the disclosure;

FIG. 6 is a schematic diagram in which a sub-pixel opening overlaps with a first electrode pattern in a sub-pixel of the display substrate provided by at least one embodiment of the disclosure;

FIG. 7 is a plane arrangement diagram of a plurality of spacers of a display substrate provided by at least one embodiment of the disclosure;

FIG. 8 is another partial section schematic diagram of a sub-pixel of a display substrate provided by at least one embodiment of the disclosure;

FIG. 9 is a circuit diagram of a pixel drive circuit of a display substrate provided by at least one embodiment of the disclosure;

FIGS. 10-14 are partial plane schematic diagrams in which respective conductive layers are stacked in sequence in a drive circuit layer of a display substrate provided by at least one embodiment of the disclosure; and

FIG. 15 is a partial section schematic diagram of a display device provided by at least one embodiment of the disclosure.

### DETAILED DESCRIPTION

In order to make objects, technical details and advantages of the embodiments of the present disclosure apparent, the technical solutions of the embodiment will be described in a clearly and fully understandable way in connection with the drawings related to the embodiments of the present disclosure. It is obvious that the described embodiments are just a part but not all of the embodiments of the present disclosure. Based on the described embodiments herein, those skilled in the art can obtain other embodiment(s), without any inventive work, which should be within the scope of the present disclosure.

Unless otherwise specified, the technical terms or scientific terms used in the present disclosure should be of general meaning as understood by those ordinarily skilled in the art. In the disclosure, words such as “first”, “second” and the like do not denote any order, quantity, or importance, but rather are used for distinguishing different components. Words such as “include” or “comprise” and the like denote that elements or objects appearing before the words of “include” or “comprise” cover the elements or the objects enumerated after the words of “include” or “comprise” or equivalents thereof, not exclusive of other elements or objects. Words such as “connected” or “connecting” and the like are not limited to physical or mechanical connections, but may include electrical connection, either direct or indirect. Words such as “up”, “down”, “left”, “right” and the like are only used for expressing relative positional relationship, when the absolute position of the described object is changed, the relative positional relationship may also be correspondingly changed.

In a display device with fingerprint recognition function, an image sensor for fingerprint recognition is usually combined with a non-display side of a display substrate of the display device. In this case, the display substrate is required to have a light transmission gap. When a finger touches a display side surface of the display device, a signal light with fingerprint information reflected by the finger will be transmitted to the image sensor through the light transmission gap, so that the image sensor can acquire the signal light for operations, such as fingerprint acquisition and recognition, etc.

In the above display device, the display substrate is required to have a stable light transmittance to ensure that the image sensor can acquire the signal light with fingerprint information for fingerprint acquisition and recognition functions. Generally, the display substrate has a variety of circuit patterns. The circuit patterns are stacked together, so that the display substrate has irregular light transmission gaps at some positions. Light transmission gaps with larger size of the irregular light transmission gaps can be used to transmit signal light with fingerprint information. Due to the preparation process errors, such as the alignment error of multiple functional layers and the size error of the circuit patterns, light transmission gaps with smaller size are often unstable, their size, number, and existence being uncertain. As a result, the whole transmittance of the display substrate is unstable, affecting the preparation yield of the display substrate.

At least one embodiment of the disclosure provides a display substrate and a display device. The display substrate has a display side and comprises a base substrate, a drive circuit layer, a first electrode layer and a pixel definition layer. The drive circuit layer is disposed on the base substrate and comprises a plurality of first gaps. The plurality of first gaps allow light from the display side to transmit therethrough. The first electrode layer is disposed on a side of the drive circuit layer away from the base substrate and comprises a plurality of first electrode patterns and a plurality of light-blocking patterns. The pixel definition layer is disposed on a side of the first electrode layer away from the base substrate and comprises a plurality of sub-pixel openings. The plurality of sub-pixel openings expose the plurality of first electrode patterns respectively. In a direction perpendicular to the base substrate, at least a portion of the plurality of light-blocking patterns do not overlap with the plurality of sub-pixel openings, the at least a portion of the plurality of light-blocking patterns correspond to and overlap with at least a portion of the plurality of first gaps, respectively, so as to at least partially shade light from the display side.

In the above display substrate provided in the embodiment of the disclosure, at least a portion of the first gaps are shaded by the light-blocking patterns, which can eliminate the instability of the first gap caused by the process variation, so as to avoid the instability of the whole light transmittance of the display substrate caused by the instability of the first gaps, that is, to improve the stability of the light transmittance of the display substrate; on the other hand, the light-blocking patterns and the first electrode patterns are disposed in a same first electrode layer, so that they can be formed in the preparation process by applying a same material and a same patterning process, which can simplify the preparation process of the display substrate.

A display substrate and a display device are described in particularly by several specific embodiments as follows.

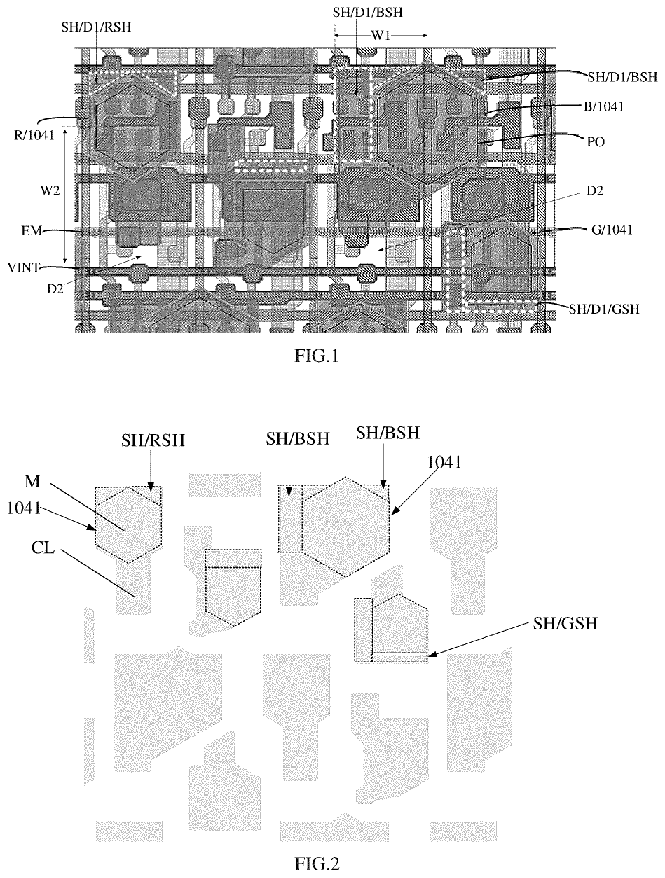

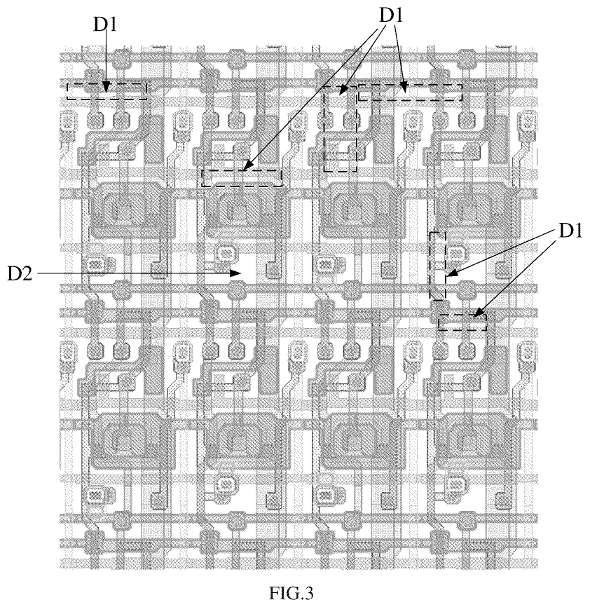

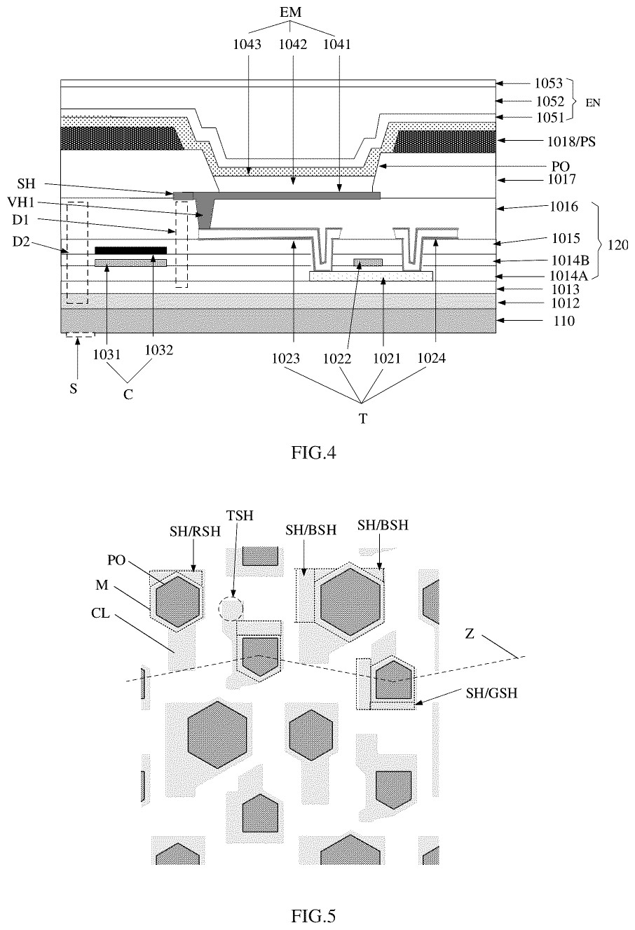

At least one embodiment of the disclosure provides a display substrate. FIG. 1 illustrates a partial plane schematic diagram of the display substrate, FIG. 2 illustrates a partial plane schematic diagram of a first electrode layer of the display device of FIG. 1, FIG. 3 illustrates a partial plane schematic diagram of a pixel drive circuit of the display substrate of FIG. 1, and FIG. 4 illustrates a partial section schematic diagram of a sub-pixel of the display substrate of FIG. 1.

As illustrated in FIG. 1-FIG. 4, the display substrate has a display side, that is, an upper side in FIG. 4, and a non-display side, that is, a lower side in FIG. 4, and comprises a base substrate 110, a drive circuit layer 120, a first electrode layer 1041 and a pixel definition layer 1017, etc.

The drive circuit layer 120 is disposed on the base substrate and comprises a plurality of first gaps D1. The plurality of first gaps D1 allow light from the display side to transmit therethrough. The first electrode layer is disposed on a side of the drive circuit layer 120 away from the base substrate 110 and comprises a plurality of first electrode patterns 1041 and a plurality of light-blocking patterns SH. The pixel definition layer 1017 is disposed on a side of the first electrode layer 1041 away from the base substrate 110 and comprises a plurality of sub-pixel openings PO. The plurality of sub-pixel openings PO expose the plurality of first electrode patterns 1041, respectively.

In a direction perpendicular to the base substrate 110, that is, in a vertical direction of FIG. 4, at least a portion of the plurality of light-blocking patterns SH (for example, all of them) do not overlap with the plurality of sub-pixel openings PO, the at least a portion of the plurality of light-blocking patterns SH (for example, all of them) correspond to and overlap with at least a portion of the plurality of first gaps D1 (for example, all of them), respectively, to at least block light from the display side.

Thus, in the embodiment of the disclosure, at least a portion of the first gaps D1 are blocked by the light-blocking patterns SH, which can eliminate the instability of the whole transmittance of the display substrate caused by the size, the number, etc. of the first gaps, that is, to improve the stability of the light transmittance of the display substrate. On the other hand, the light-blocking patterns and the first electrode patterns are disposed in a same first electrode layer, so that they can be formed in the preparation process by applying a same material and a same patterning process, which can simplify the preparation process of the display substrate.

For example, in some embodiments, a width of the plurality of first gaps is less than or equal to 4.0 micrometers, for example, less than or equal to 3.0 micrometers, less than or equal to 2.0 micrometers, less than or equal to 1.5 micrometers or less than or equal to 1.0 micrometer. The width of the first gap D1 refers to a size of the first gap D1 perpendicular to its extension direction. For example, when the first gap D1 has a rectangle shape (or approximate rectangle shape), its width is a short side length of the rectangle. When the first gap D1 has an irregular shape, a direction of the longest span of the irregular shape is the extension direction, and a size perpendicular to the extension direction is the width of the first gap D1.

Since the first gap D1 with smaller width is more likely to be subjected to large process errors during the preparation process, such as large size deviations, etc., the first gap D1 with smaller width is more likely to cause a large deviation of the whole light transmittance of the display substrate. By using the light-blocking pattern SH to shade the first gap D1 with smaller width, the stability of the whole light transmittance of the display substrate can be greatly improved.

For example, in some embodiments, a distance W1 from the plurality of first gaps D1 to a center of the plurality of sub-pixel openings PO is less than 33 micrometers. For example, with reference to FIG. 1, the distance W1 from the edge of the plurality of first gaps D1 away from the plurality of sub-pixel openings PO to a center of the plurality of sub-pixel openings PO is less than 33 micrometers. That is, the plurality of first gaps D1 are distributed in the range of 33 micrometers from the center of the plurality of sub-pixel openings PO.

For example, in some embodiments, at least a portion of the plurality of light-blocking patterns SH are integrally connected to the plurality of first electrode patterns 1041, respectively. In this case, as illustrated in FIGS. 1 and 2, the first electrode pattern 1041 and the light-blocking pattern SH which are integrally connected has an irregular shape in a whole.

For example, in some embodiments, the display substrate has a plurality of sub-pixels arranged in array. Each of the plurality of sub-pixels comprises a light emitting device EM, and the plurality of first electrode patterns 1041 are used as anodes of the light-emitting devices EM of the plurality of sub-pixels, respectively. As illustrated in FIG. 4, the light emitting device EM further comprises a light emitting material layer 1042 disposed on a side of the first electrode pattern 1041 away from the base substrate 110 and a second electrode layer 1043 disposed on a side of the light emitting material layer 1042 away from the base substrate 110.

For example, in some embodiments, as illustrated in FIG. 2, the first electrode pattern 1041 comprises a main part M and a connection part CL, and the connection part CL extends from the main part M. The main part M is used to drive the light-emitting device. For example, the light-emitting material layer 1042 directly contacts at least a portion of the main part M, to drive by the main part M. The connection part CL is used to electrically connect the main part M with the pixel drive circuit. The connection part CL will not directly contact with the portion of the light emitting material layer 1042 for light emitting.

For example, as illustrated in FIG. 2, a plane shape of the main part M of each of the plurality of first electrode patterns 1041 is a polygon (such as, hexagon, pentagons, quadrilaterals, etc.) or a shape with arc edges (such as, circle, oval, mango, etc.), respectively, and a plane shape of each of the plurality of light-blocking patterns SH is a polygon, such as, triangle or quadrilateral (such as, rectangle, parallelogram, diamond, etc.) and the like.

For example, in some embodiments, the plurality of sub-pixels comprises a red sub-pixel R, a green sub-pixel G and a blue sub-pixel B. For example, as illustrated in FIGS. 1 and 2, a plane shape of the main part M of the first electrode pattern 1041 of the light emitting device of the red sub-pixel R is hexagon (hereinafter referred as first hexagon), and a shape of the light-blocking patterns RSH integrally connected with the first electrode pattern 1041 of the light emitting device of the red sub-pixel is triangle. For example, a number of light-blocking patterns RSH integrally connected with the first electrode pattern 1041 of the light emitting device of the red sub-pixel R is two, and the two light-blocking patterns are arranged symmetrically.

For example, in some embodiments, as illustrated in FIGS. 1 and 2, a plane shape of the main part M of the first electrode pattern 1041 of the light emitting device of the blue sub-pixel B is hexagon (hereinafter referred as second hexagon). A shape of the second hexagon is similar to that of the first hexagon, for example, and a size of the second hexagon is greater than that of the first hexagon. For example, the light-blocking pattern BSH integrally connected with the first electrode pattern 1041 of the light emitting device of the blue sub-pixel B is triangle or rectangular. For example, a number of light-blocking patterns BSH integrally connected with the first electrode pattern 1041 of the light emitting device of the blue sub-pixel B is three, and the three light-blocking patterns BSH are integrally connected with three edges of the first electrode pattern 1041 of the light emitting device of the blue sub-pixel B.

For example, as illustrated in FIGS. 1 and 2, the three light-blocking patterns BSH comprise two triangular light-blocking patterns and a rectangular pattern. The two triangular light-blocking patterns are symmetrically distributed, and the rectangular pattern is connected with a left side of the first electrode pattern 1041 and a left side of the triangle.

For example, in some embodiments, as illustrated in FIGS. 1 and 2, a plane shape of the main part M of the first electrode pattern 1041 of the light emitting device of the green sub-pixel G is pentagon, and a shape of the light-blocking pattern G integrally connected with the first electrode pattern 1041 of the light emitting device of the green sub-pixel G is rectangular. For example, a number of the light-blocking pattern GSH integrally connected with the first electrode pattern 1041 of the light emitting device of the green sub-pixel G is one or two, and the one or two light-blocking patterns GSH are integrally connected with one edge or two edges of the first electrode pattern 1041 of the light emitting device of the green sub-pixel G, respectively.

For example, in some embodiments, one red sub-pixel R, two green sub-pixels G and one blue sub-pixel B constitute a pixel unit, and a plurality of pixel units are arranged on the base substrate 110 in array. For example, as illustrated in FIGS. 1 and 2, the first electrode pattern 1041 of the light emitting device of one of the two green sub-pixels G is connected with one rectangular light-blocking pattern GSH, and the first electrode pattern 1041 of the light emitting device of the other one of the two green sub-pixels G is connected with two rectangular light-blocking patterns GSH.

For example, the light emitting devices of the red sub-pixels R and the blue sub-pixels B are located in the same rows, the light emitting devices of the green sub-pixels are substantially located in the same rows, and the rows where the light emitting devices of the red sub-pixels and the blue sub-pixels are located and the rows where the light emitting devices of the green sub-pixels are located are arranged alternately.

For example, in the embodiment of the disclosure, the light emitting devices of the green sub-pixels G are substantially located in the same row, which refers to, with reference to FIG. 5, at least portions of the light emitting devices of any two adjacent green sub-pixels G are located on a same straight line, and the light-emitting devices of the two adjacent green sub-pixels G can be offset relative to a direction of the row. That is, a line connecting centers of the light-emitting devices of any two adjacent green sub-pixels G can be a broken line Z.

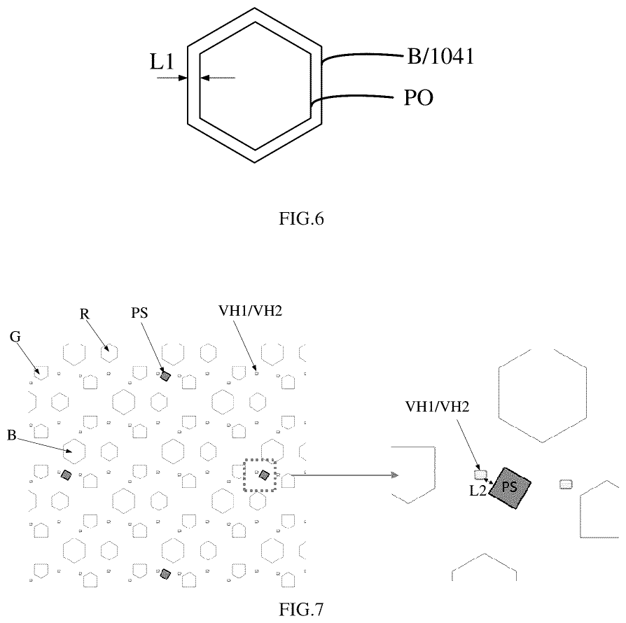

For example, FIG. 5 illustrates a plane schematic diagram in which the first electrode and the pixel definition layer are stacked, and FIG. 6 illustrates a plane schematic diagram in which the main part of the bule sub-pixel and the sub-pixel opening are stacked. In some embodiments, as illustrated in FIGS. 5 and 6, in a sub-pixel opening PO and a first electrode pattern 1041 corresponding to each other, a shape of the sub-pixel opening PO is the same as that of the main part M of the first electrode pattern 1041. A first orthographic projection of the sub-pixel opening PO on the base substrate 110 is within a second orthographic projection of the main part M of the first electrode pattern 1041 on the base substrate 110, and a minimum distance between an edge of the first orthographic projection and an edge of the second orthographic projection is from 1.5 micrometers to 3.5 micrometers, such as 2.0 micrometers, 2.5 micrometers or 3.0 micrometers. Therefore, the sub-pixel opening PO fully exposes the first electrode pattern 1041, and a region limited by the sub-pixel opening PO is an effective light emitting region of the light-emitting device EM. The light emitting material layer 1042 directly contact with the main part M of the first electrode pattern 1041 in the region to be driven.

For example, in some embodiments, as illustrated in FIG. 5, the first electrode pattern 1041 of the green sub-pixel G of each of the pixel units can further comprise a transistor light-blocking pattern TSH. The transistor light-blocking pattern TSH is used to shade a thin film transistor (such as, a thin film transistor T2 hereinafter) disposed there below, so as to prevent light from irradiating the thin film transistor, thereby affecting the switching performance of the thin film transistor.

For example, in some embodiments, as illustrated in FIGS. 1 and 3, the drive circuit layer 120 further comprises a plurality of second gaps D2. The plurality of second gaps D2 allow light from the display side to transmit therethrough. In the direction perpendicular to the base substrate 110, the plurality of second gaps D2 do not overlap with the plurality of first electrode patterns 1041 and the plurality of light-blocking patterns SH. Thus, the second gaps D2 can allow light from the display side to transmit to the non-display side of the display substrate. For example, when an image sensor S is disposed on the non-display side of the display substrate, the second gap D2 can transmit the signal light with finger information to the image sensor S.

For example, in some embodiments, a width of at least some second gaps D2 of the plurality of second gaps D2 is greater than 1.0 micrometer, or greater than 1.5 micrometers, or greater than 2.0 micrometers, or greater than 3.0 micrometers, or greater than 4.0 micrometers. The width of the second gap D2 refers to a size of the second gap D2 perpendicular to an extension direction of the second gap D2. Thus, the size of the second gap D2 is larger, which can fully realize the light transmission function. Moreover, because the size of the second gap D2 is larger, no large deviation of the preparation process will occur. Even if the small deviation occurs, it will have little affection on the whole transmittance stability of the display substrate.

For example, in some embodiments, a distance W2 from the plurality of second gaps D2 to a center of the plurality of sub-pixel openings PO is greater than 33 micrometers. For example, referring to FIG. 1, a distance W2 from an edge of the plurality of second gaps D2 away from the sub-pixel opening D2 to a center of the sub-pixel opening PO is greater than 33 micrometers.

For example, in some embodiments, as illustrated in FIG. 1, an orthographic projection of each of the plurality of second gaps D2 on the base substrate 110 is located between an orthographic projection of a light emitting control signal line EM on the base substrate 110 and an orthographic projection of a reset voltage lines VINT closest to the light emitting control signal line EM on the base substrate 110. The connection relationship between the light emission control signal line EM and the reset voltage line VINT and their usage will be described in detail later.

For example, as illustrated in FIG. 1, an orthographic projection of each of at least a portion of the plurality of second gap D2 (for example, the second gap D2 on right side of FIG. 1) on the base substrate 110 is located between an orthographic projection of a light emitting control signal line EM for the blue sub-pixel B on the base substrate 110 and an orthographic projection of a reset voltage lines VINT for the red sub-pixel R on the base substrate 110. The red sub-pixel R is located in a row next to the row where the blue sub-pixel B is located and is adjacent to the blue sub-pixel B.

For example, as illustrated in FIG. 1, an orthographic projections of each of at least a portion of the plurality of second gaps D2 (for example, the second gap on left side of FIG. 1) on the base substrate 110 is located between an orthographic projection of a light emitting control signal line EM for the red sub-pixel R on the base substrate 110 and an orthographic projections of a reset voltage line VINT for the blue sub-pixel B on the base substrate 110. The above blue sub-pixel B is located in a row next to the row where the red sub-pixel R is located and is adjacent to the red sub-pixel R.

That is, in the embodiment of the disclosure, the plurality of second gaps D2 are located in gaps between the pixel drive circuits of the blue sub-pixel B and the red sub-pixel R.

For example, in some embodiments, as illustrated in FIG. 4, the drive circuit layer 120 comprises a plurality of pixel drive circuits and a first planarization layer 1016. The pixel drive circuit comprises a plurality of thin film transistors and at least one storage capacitor. For example, it can have the structures, such as 2T1C (that is, two thin film transistors and a storage capacitor), 7T1C (that is, seven thin film transistors and a storage capacitor) or 8T2C (that is, eight thin film transistors and a storage capacitor), etc. The specific structure of the pixel drive circuit is not limited in the embodiments of the disclosure.

For example, FIG. 4 illustrates a thin film transistor T and a storage capacitor C electrically connected with the light emitting device EM. As illustrated in FIG. 4, the thin film transistor T comprises an active layer 1021, a gate electrode 1022, a first source/drain electrode 1023 and a second source/drain electrode 1024. The storage capacitor C comprises a first capacitor electrode 1031 and a second capacitor electrode 1032. The first capacitor electrode 1031 is disposed in the same layer as the gate electrode 1022.

It should be noted that, in the embodiment of the disclosure, “disposed in the same layer” means that two functional layers or two structure layers are in the same layer and formed of the same material. That is, in the preparation process, the two functional layers or structure layers can be formed of the same material layer, and the required patterns and structures can be formed by the same patterning process.

For example, as illustrated in FIG. 4, the first planarization layer 1016 is disposed on a side of the plurality of pixel drive circuits away from the base substrate 1011 and comprises a plurality of firs via holes VH1. The plurality of first via holes VH1 respectively expose output terminals of the plurality of pixel drive circuits, for example, the first source-drain electrode 1023. The first electrode layer is disposed on a side of the first planarization layer 1016 away from the base substrate 110, and the plurality of first electrode patterns 1041 are connected with the output terminals of the plurality of pixel drive circuit through the plurality of first via holes VH1, respectively. Thus, the pixel drive circuit can control the voltage applied on the first electrode pattern 1041 by the thin film transistor T.

For example, as illustrated in FIG. 4, the display substrate further comprises a spacer layer 1018 disposed on a side of the pixel definition layer 1017 away from the base substrate 110. The spacer layer 1018 comprises a plurality of spacers PS. For example, in the direction perpendicular to the base substrate 110, that is, in a vertical direction in FIG. 4, a height of each of the plurality of spacers PS is from 1.8 micrometers to 2.4 micrometers, such as 2.0 micrometers or 2.2 micrometers. Thus, the spacer PS can have an enough height, so that, in the preparation process of the display substrate, for example, when the light emitting material layer 1042 is formed by evaporation etc., the adopted mask plate can be fully supported on the plurality of spacer PS, without defects such as scratching the structure of the display substrate due to deformation of the mask plate, etc.

For example, in some embodiments, in the direction perpendicular to the base substrate 110, the plurality of spacers PS do not overlap with the plurality of first via holes VH1. Because the first via hole VH1 is formed by hollowing out a portion of the material of the first planarization layer 1016, the material above the first via hole VH1 is likely to depress. If the spacer PS is formed above the first via hole VH1, it will cause the spacer PS to sink, and thus the height of the spacer PS relative to the base substrate 110 will be reduced, which will affect the support function of the spacer PS. The plurality of spacer PS do not overlap with the plurality of first vias VH1, so that the plurality of spacer PS can effectively realize the support function.

For example, FIG. 7 illustrates a plane arrangement schematic diagram of a plurality of spacers PS. As illustrated in FIG. 7, in some embodiments, in a direction parallel to the base substrate 110, a minimum distance between the plurality of spaces PS and the plurality of first via holes VH1 is greater than 2.0 micrometers. Because a sidewall of the first via hole VH1 is usually an inclined sidewall, the material formed above the first via hole VH1 is also likely to depress around the first via hole VH1. Therefore, by arranging the spacer PS away from the first via hole VH1 by a certain distance, the affection on the spacer PS which may be caused by the first via hole VH1 can be fully avoided, so that the spacer PS has an enough height to fully realize the support function.

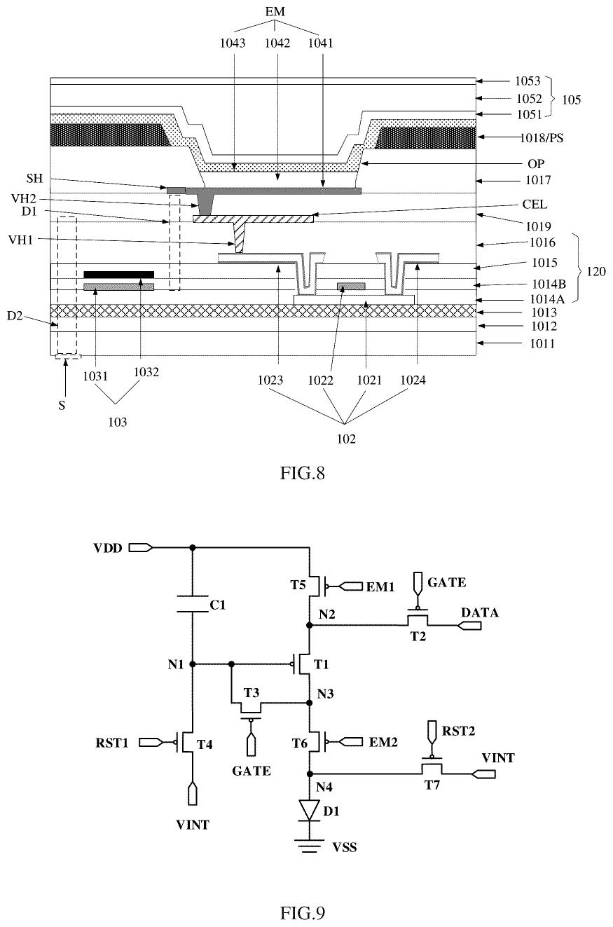

For example, in other embodiments, FIG. 8 illustrates another partial section schematic diagram of a sub-pixel on the display substrate. As illustrated in FIG. 8, the drive circuit layer comprises a plurality of pixel drive circuits, a first planarization layer 1016, a connection electrode layer and a second planarization layer 1019. The specific structure of the pixel drive circuit can be referred to above embodiments, which will be omitted here.

As illustrated in FIG. 8, the first planarization layer 1016 is disposed on a side of the plurality of pixel drive circuits away from the base substrate 110 and comprises a plurality of firs via holes VH1. The plurality of first via holes VH1 expose output terminals of the plurality of pixel drive circuits respectively, for example, the first source/drain electrode 1023. The connection electrode layer is disposed on a side of the first planarization layer 1016 away from the base substrate 110 and comprises a plurality of connection electrodes CEL. The plurality of connection electrodes CEL are connected with output terminals of the plurality of pixel drive circuits through the first via holes VH1, respectively. The second planarization layer 1019 is disposed on a side of the connection electrode layer away from the base substrate 110 and comprises a plurality of second via holes VH2. The plurality of second via holes VH2 expose the plurality of connection electrodes CEL. The first electrode layer is disposed on a side of the second planarization layer 1019 away from the base substrate 110, and the plurality of first electrode patterns 1041 are electrically connected with the plurality of connection electrodes CEL through the plurality of second via holes VH2, respectively.

As illustrated in FIG. 8, the display substrate further comprises a spacer layer 1018 disposed on a side of the pixel definition layer 1017 away from the base substrate 110, and the spacer layer 1018 comprises a plurality of spacer PS. For example, in the direction perpendicular to the base substrate 110, that is, in a vertical direction in FIG. 4, a height of each of the plurality of spacers PS is from 1.8 micrometers to 2.4 micrometers, such as 2.0 micrometers or 2.2 micrometers. For example, in the direction perpendicular to the base substrate 110, the plurality of spacers PS do not overlap with the plurality of second via holes VH2. For example, referring to FIG. 7, in a direction parallel to the base substrate 110, a minimum distance L2 between the plurality of spaces PS and the plurality of second via holes VH2 is greater than 2.0 micrometers. Thus, the affection on the spacer PS which may be caused by second via hole VH2 can be fully avoided, so that the spacer PS has an enough height to fully realize the support function.

For example, in the embodiment of the disclosure, in the direction perpendicular to the base substrate 110, a plurality of pixel drive circuits at least partially overlap with the plurality of sub-pixel openings PO. In this case, the light emitting devices formed in the sub-pixel openings PO can be top emission light emitting devices.

For example, as illustrated in FIGS. 4 and 8, the display substrate can further comprise a barrier layer 1012 and a buffer layer 1013 disposed on the base substrate 110. The barrier layer 1012 and the buffer layer 1013 can prevent impurities in the base substrate 110 from entering a plurality of functional layers of the display substrate 110, thereby having protection function. For example, the barrier layer 1012 and the buffer layer 1013 can be formed by one or more of inorganic insulation materials, such as silicon oxide, silicon nitride or silicon oxynitride, etc.

For example, as illustrated in FIGS. 4 and 8, the display substrate can further comprise a first gate insulation layer 1014A disposed on a side of the active layer 1021 away from the base substrate 110, a second gate insulation layer 1014B disposed on a side of the gate electrode 1022 and the first capacitor electrode 1031 away from the base substrate 110, and an interlayer insulation layer 1015 disposed on a side of the second capacitor electrode 1032 away from the base substrate 110. For example, the first gate insulation layer 1014A, the second gate insulation layer 1014B and the interlayer insulation layer 1015 can be formed by one or more of inorganic insulation materials, such as silicon oxide, silicon nitride or silicon oxynitride, etc.

For example, as illustrated in FIGS. 4 and 8, the display substrate can further comprise an encapsulation layer EN disposed on a side of the light emitting device EM away from the base substrate 110, and the encapsulation layer EN can be a composite encapsulation layer including a first inorganic encapsulation layer 1051, a first organic encapsulation layer 1052 and a second inorganic encapsulation layer 1053. The first inorganic encapsulation layer 1051 and the second inorganic encapsulation layer 1053 can be formed by one or more of inorganic insulation materials, such as silicon oxide, silicon nitride or silicon oxynitride, etc. The first organic encapsulation layer 1052 can be formed by one or more of organic insulation materials, such as resin and polyimide, etc.

For example, in one embodiment, the pixel drive circuit of the sub-pixel has a 7T1C structure. FIG. 9 illustrates a circuit diagram of the pixel drive circuit of the 7T1C structure. As illustrated in FIG. 9, the pixel drive circuit with 7T1C structure comprises seven thin film transistors T1-T7 and a storage capacitor C1, and has a connection relationship as illustrated in the figure. The pixel drive circuit has, for example, following four stages of driving process. In following description, the seven thin film transistors T1-T7 are all P-type transistors, that is, the gate electrode of each of the transistors is turned on when it is input with a low level and is turned off when it is turned off when it is input with a high level.

In an initialization stage 1, a first reset signal RST1 is input, to turn on the fourth transistor T4, and a reset voltage VINT is applied to a control terminal (such as, the gate electrode) of the drive transistor T1; a first light emission control signal EM1 is input, to turn on the fifth transistor T5, and a first voltage VDD is applied to a second node N2.

For example, in the initialization stage 1, the fourth transistor T4 is turned on by a low level of a first reset signal RST1, and the fifth transistor T5 is turned on by a low level of the first light emission control signal EM1. At the same time, the second transistor T2, the third transistor T3, the sixth transistor T6 and the seventh transistor T7 are turned off by respective input high level signals.

In the initialization stage 1, because the fourth transistor T4 is turned on, a reset voltage VINT (a low level signal, such as grounding or other low level signals) can be applied to the gate electrode of the first transistor T1. At the same time, because the fifth transistor T5 is turned on, the first voltage VDD (high level signal) can be applied to the source electrode of the first transistor T1, so that, in the initialization stage 1, the voltage VGS of the gate electrode and source electrode of the first transistor T1 can satisfy |VGS|>|Vth| (Vth is a threshold voltage of the first transistor T1, for example, when the first transistor T1 is a P-type transistor, Vth is negative), so that the first transistor T1 is in an on state in which VGS is fixed biased.

In a data writing and compensation stage 2, a scan signal GATE and a data signal DATA are input, to turn on the second transistor T2, the drive transistor T1 and the third transistor T3. The data signal DATA is written into the drive transistor T1, and the third transistor T3 performs threshold compensation on the drive transistor T1.

In the data writing and compensation stage 2, the second transistor T2 and the third transistor T3 are turned on by a low level of the scan signal GATE. At the same time, the fourth transistor T4, the fifth transistor T5, the sixth transistor T6 and the seventh transistor T7 are turned off by respective input high level signals.

In the data writing and compensation stage 2, the data signal DATA charges the first node N1 via the second transistor T2, the first transistor T1 and the third transistor T3 (that is, charges the storage capacitor C1), that is, a potential of the first node N1 gradually increases. It is ready to understand that, because the second transistor T2 is turned on, a potential of the second node N2 is kept at Vdata, and at the same time, according to the characteristics of the first transistor T1, when the potential of the first node N1 increases to Vdata+Vth, the first transistor T1 is turned off and the charging process ends. It should be noted that Vdata represents a voltage value of data signal DATA, and Vth represents a threshold voltage of the first transistor.

After the data writing and compensation stage 2, the potentials of the first node N1 and the third node N3 are both Vdata+Vth, that is, voltage information with the data signal DATA and the threshold voltage Vth is stored in the storage capacitor C1, which is used to provide gray scale display data and compensate the threshold voltage of the first transistor T1 itself in a subsequent light emitting stage.

In a reset stage 3, a second light emission control signal EM2 and a second reset signal RST2 are input, to turn on the sixth transistor T6 and the seventh transistor T7, so as to reset the first transistor T1, the third transistor T3 and the sixth transistor T6.

In the reset phase 3, the sixth transistor T6 is turned on by a low level of the second light emission control signal EM2, and the seventh transistor T7 is turned on by a low level of the second reset signal RST2. At the same time, the second transistor T2, the third transistor T3, the fourth transistor T4, and the fifth transistor T5 are turned off by respective input high levels.

In the reset stage 3, because the reset voltage VINT is a low level signal (for example, grounding or other low level signals), the drain electrode of the first transistor T1 is discharged via the sixth transistor T6 and the seventh transistor T7, thereby resetting the potentials of the third node N3 and the fourth node N4 simultaneously.

In the reset stage 3, the drain electrode of the first transistor T1 is reset, so that it can be kept at a fixed potential, and the display effect of the display device with the pixel circuit will not be affected by the uncertainty of the drain electrode potential. At the same time, the fourth node N4 is also reset, that is, the OLED is reset, so that the OLED can be displayed in a black state before the light emitting stage 4, and the display effect, such as contrast, of the display device with the pixel circuit is improved.

In the light emitting stage 4, the first light emitting control signal EM1 and the second light emitting control signal EM2 are input, to turn on the thin film transistor T5, the thin film transistor T6 and the drive thin film transistor T1, and the thin film transistor T6 applies a drive current to the light emitting element 600 for emitting light.

In the light emitting stage 4, the fifth transistor T5 is turned on by a low level of the first light emitting control signal EM1, the sixth transistor T6 is turned on by a low level of the second light emitting control signal EM2, and the second transistor T2, the third transistor T3, the fourth transistor T4, and the seventh transistor T7 are turned off by respective input high levels. At the same time, the potential of the first node N1 is Vdata+Vth, and the potential of the second node N2 is VDD, and thus the first transistor T1 is also kept at an on state.

As illustrated in FIG. 8, in the light emitting stage 4, the first electrode pattern (such as, anode) and the second electrode layer (such as, cathode) of the light emitting device D1 are respectively input with the first voltage VDD (high voltage) and the second voltage VSS (low voltage), thereby emitting light under the action of the drive current flowing through the first transistor T1.

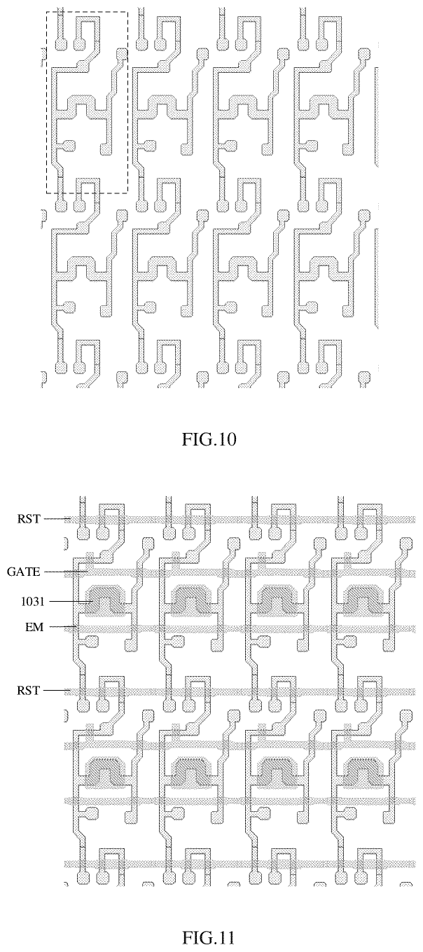

For example, FIGS. 10-14 illustrate a partial plan schematic diagram of respective conductive layers of the drive circuit layer stacked in sequence. Insulation layers (for example, the above gate insulation layer and the interlayer insulation layer) are disposed between adjacent conductive layers. The insulation layers have a plurality of via holes for electrical connection therein. In following embodiments, respective conductive layers will be described on emphasis, and the insulation layers will be omitted.

For example, FIG. 10 illustrates a plan schematic diagram of a semiconductor layer of the drive circuit layer. The semiconductor layer comprises active layers of respective thin film transistors T1-T7. For example, the active layers of the thin film transistors T1-T7 are integrally connected to each other to a structure. For example, a portion of the semiconductor layer circled by dotted lines in FIG. 10 is the active layers of the thin film transistors T1-T7 of the pixel drive circuit of the sub-pixel. For example, a first gate insulation layer 1014A is disposed above the semiconductor layer, which is not illustrated in the figure.

For example, FIG. 11 illustrates a plan schematic diagram in which the first conductive layer of the drive circuit layer is stacked on the semiconductor layer of FIG. 10. As illustrated in FIG. 11, the first conductive layer comprises a gate electrode of each of the transistors, a first capacitor electrode plate 1031 of the storage capacitor, and some scan lines GATE, light emission control lines EM and reset control lines RST. For example, the gate electrode of each of the transistors is a portion of the scan line GATE, the light emission control line EM and the reset control line RST that overlaps with the active layer, respectively. For example, each row of the sub-pixels is correspondingly connected with a scan line GATE, two reset control lines RST and an emission control line EM. The first gate insulation layer 1014B is disposed on the first conductive layer which is not illustrated in the figure.

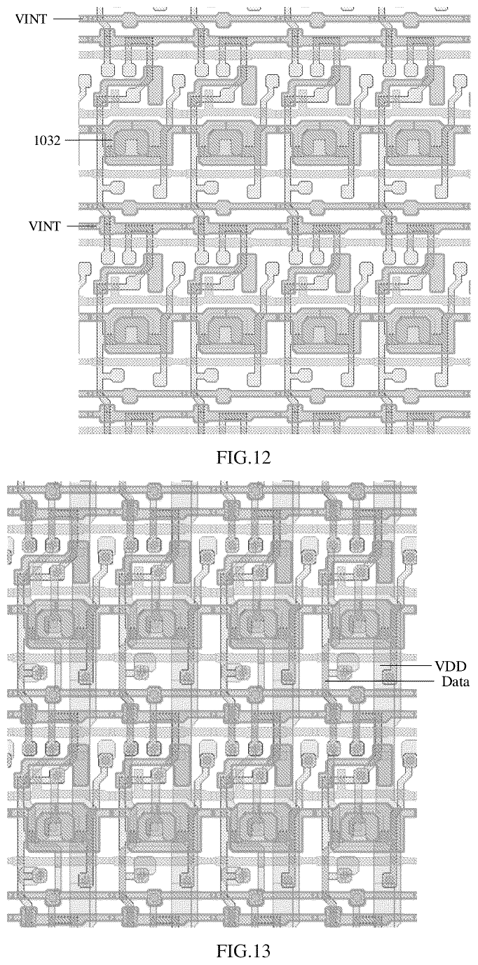

For example, FIG. 12 illustrates a plan schematic diagram in which the second conductive layer of the drive circuit layer is stacked on the stacked structure of FIG. 11. As illustrated in FIG. 12, the second conductive layer comprises a second capacitor electrode plate 1032 of the storage capacitor and a plurality of reset voltage lines VINT. An interlayer insulation layer 1015 is disposed on the second conductive layer, which is not illustrated in the figure.

For example, FIG. 13 illustrates a plan schematic diagram in which the third conductive layer of the drive circuit layer is stacked on the stacked structure of FIG. 12. As illustrated in FIG. 13, the third conductive layer comprises a first power supply line VDD, a portion of the data lines Data, source/drain electrodes of the thin film transistors T1-T7, etc. A planarization layer 1016 is disposed on the third conductive layer, which is not illustrated in the figure.

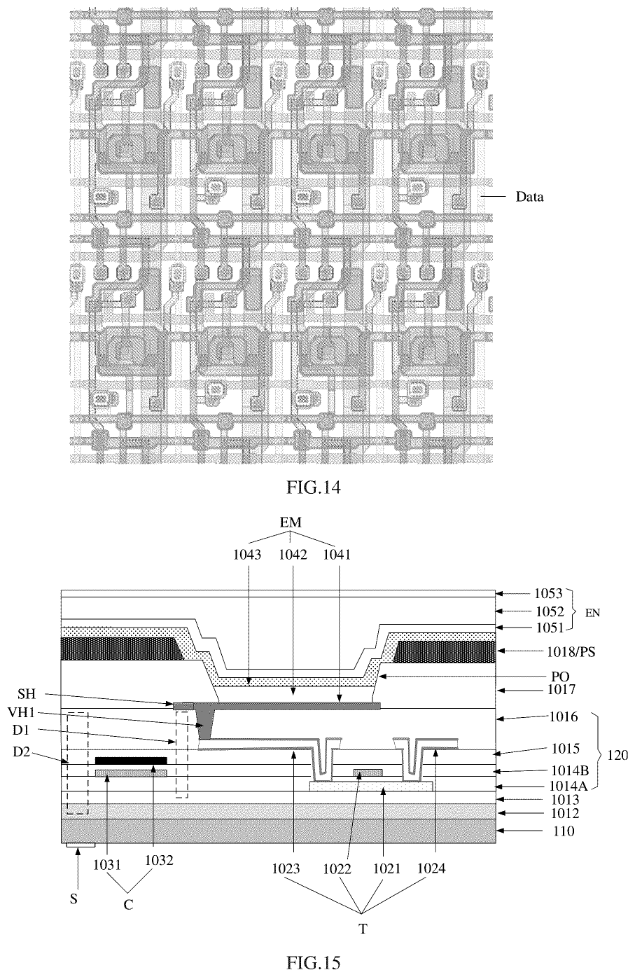

For example, FIG. 14 illustrates a plan schematic diagram in which a fourth conductive layer of the drive circuit layer is stacked on the stacked structure of FIG. 13. As illustrated in FIG. 13, the fourth conductive layer comprises another portion of the data lines Data. For example, in some embodiments, the fourth conductive layer can further comprise a connection electrode CEL. A planarization layer 1019 is disposed above the third conductive layer, which is not illustrated in the figure. Thus, in the embodiment, the data lines Data is distributed in two conductive layers to facilitate the arrangement of the data lines Data.

For example, FIG. 1 illustrates a plan schematic diagram in which the first electrode layer is stacked on the stacked structure of FIG. 14. The details are referred to the description of FIG. 1, which will be omitted here.

For example, in the embodiment of the disclosure, the base substrate 110 can be a rigid substrate formed by glass or quartz etc. or a flexible substrate formed by polyimide etc. The gate electrode 1022 can be formed by a metal material such as copper (Cu), aluminum (Al), titanium (Ti), molybdenum (Mo), etc. or an alloy material, for example, to form as a single metal layer structure or a multi-layer metal layer structure such as titanium/aluminum/titanium, etc. The first source/drain electrode 1023 and the first source/drain electrode 1024 can be formed by a metal material such as copper (Cu), aluminum (Al), titanium (Ti), molybdenum (Mo), etc. or an alloy material, for example, to form a single metal layer structure or a multi-layer metal layer structure such as titanium/aluminum/titanium, etc. A material of the first electrode 1031 and the second electrode 1032 comprises a metal such as aluminum, titanium, cobalt and copper etc. or an alloy material. The active layer 1021 can be formed by a material such as polysilicon and metal oxide etc.

For example, the first planarization layer 1016, the second planarization layer 1019, the pixel defining layer 1017, the spacer layer 1018, and the first organic encapsulation layer 1052 of the encapsulation layer EN can be formed by an organic insulation material such as polyimide and resin etc.

For example, the display substrate can further comprise other structures in addition to the above structures. The details are referred to the related art, which will be omitted here.

In addition, it should be noted that the material of each of function layers is not limited in the embodiments of the disclosure, and the material of each of function layers is not limited to the above examples. In the embodiment of the disclosure, each of the thin film transistors can be a P-type thin film transistor or an N-type thin film transistor, and the structure can be a bottom-gate type, a top-gate type or a double-gate type. The structure illustrated in the attached drawings is only illustrated as an example, and the embodiment of the disclosure does not limit the specific form of each of the thin film transistors. For example, in some embodiments, when the thin film transistor is of the double-gate type, the display substrate of FIGS. 4 and 8 has at least one more conductive layer and one more insulation layer, and another gate electrode is arranged in the conductive layer. In this case, the two gate electrodes can be located on a side of the active layer of the thin film transistor close to the base substrate and a side of the active layer of the thin film transistor away from the base substrate, respectively.

At least one embodiment of the disclosure provides a display device and the display device comprises any of the above display substrates. For example, FIG. 15 illustrates a partial section schematic diagram of the display device. As illustrated in FIG. 15, the display device can further comprise an image sensor S combined on the non-display side of the display substrate and configured to receive the light transmitted from the second gap D2. For example, in some embodiments, the orthographic projection of the image sensor S on the base substrate 110 at least partially overlaps with the orthographic projection of the second gap D2 on the base substrate 110.

For example, the image sensor S can be a variety of suitable types of image sensors such as a charge coupled device (CCD) image sensor, a complementary metal oxide semiconductor (CMOS) image sensor or a photodiode (such as PIN photodiode), etc. As required, the image sensor can sense only a certain wavelength of light (such as red light or green light) or all visible light.

For example, the display device can be a mobile phone, a tablet computer, a television, a display, a laptop, a digital photo frame, a navigator and other products or components with display function.

Herein, some points need to be explained:
(1) Drawings of the embodiments of the present disclosure only refer to structures related with the embodiments of the present disclosure, and other structures may refer to general design.
(2) For clarity, in the drawings used to describe embodiments of the present disclosure, the thickness of layers or regions is enlarged or reduced, i.e., these drawings are not drawn to actual scale.
(3) In case of no conflict, features in the same embodiment and different embodiments of the present disclosure may be combined with each other.

The foregoing embodiments merely are exemplary embodiments of the present disclosure, and not intended to define the scope of the present disclosure, and the scope of the present disclosure is determined by the appended claims.

1. A display substrate, having a display side and comprising:
a base substrate,
a drive circuit layer, disposed on the base substrate, comprising a plurality of first gaps, wherein the plurality of first gaps allow light from the display side to transmit therethrough,
a first electrode layer, disposed on a side of the drive circuit layer away from the base substrate and comprising a plurality of first electrode patterns and a plurality of light-blocking patterns,
a pixel definition layer, disposed on a side of the first electrode layer away from the base substrate and comprising a plurality of sub-pixel openings, wherein the plurality of sub-pixel openings expose the plurality of first electrode patterns, respectively,
wherein, in a direction perpendicular to the base substrate, at least a portion of the plurality of light-blocking patterns do not overlap with the plurality of sub-pixel openings, the at least a portion of the plurality of light-blocking patterns correspond to and at least partially overlapped with at least a portion of the plurality of first gaps, respectively, so as to at least partially block light from the display side.

2. The display substrate according to claim 1, wherein a width of the plurality of first gaps is less than or equal to 4.0 micrometers.

3. The display substrate according to claim 1, wherein a distance of the plurality of first gaps from a center of the plurality of sub-pixel openings is less than 33 micrometers.

4. The display substrate according to claim 1, wherein the at least a portion of the plurality of light-blocking patterns are integrally connected to the plurality of first electrode patterns, respectively.

5. The display substrate according to claim 1, wherein each of the plurality of first electrode patterns comprises a main part and a connection part, and a plane shape of the main part is polygon or a shape with arc edge, and a plane shape of the plurality of light-blocking patterns is polygon.

6. The display substrate according to claim 1, wherein the display substrate comprises a plurality of sub-pixels, each of the plurality of sub-pixels comprises a light emitting device, and the plurality of first electrode patterns are used as anodes of the light-emitting devices of the plurality of sub-pixels, respectively.

7. The display substrate according to claim 6, wherein the plurality of sub-pixels comprises red sub-pixels, green sub-pixels and blue sub-pixels,
wherein a plane shape of the main part of the first electrode pattern of the light emitting device of each of the red sub-pixels is hexagon, and a shape of the light-blocking pattern integrally connected with the first electrode pattern of the light emitting device of each of the red sub-pixel is triangle.

8. The display substrate according to claim 7, wherein a number of light-blocking patterns integrally connected with the first electrode pattern of the light emitting device of each of the red sub-pixel is two, and the two light-blocking patterns integrally connected with the first electrode pattern of the light emitting device of each of the red sub-pixels are arranged symmetrically.

9. The display substrate according to claim 7, wherein a plane shape of the main part of the first electrode pattern of the light emitting device of each of the blue sub-pixels is hexagon, and a shape of the light-blocking patterns integrally connected with the first electrode pattern of the light emitting device of each of the blue sub-pixels is triangle or rectangular.

10. The display substrate according to claim 9, wherein a number of light-blocking patterns integrally connected with the first electrode pattern of the light emitting device of each of the blue sub-pixels is three, and the three light-blocking patterns integrally connected with the first electrode pattern of the light emitting device of each of the blue sub-pixels are integrally connected with three edges of the first electrode pattern of the light emitting device of each of the blue sub-pixels.

11. The display substrate according to claim 7, a plane shape of the main part of the first electrode pattern of the light emitting device of each of the green sub-pixels is pentagon, and a shape of the light-blocking patterns integrally connected with the first electrode pattern of the light emitting device of each of the green sub-pixels is rectangular.

12. The display substrate according to claim 11, wherein a number of light-blocking patterns integrally connected with the first electrode pattern of the light emitting device of each of the green sub-pixels is one or two, and the one or two light-blocking patterns integrally connected with the first electrode pattern of the light emitting device of each of the green sub-pixels are integrally connected with one edge or two edges of the first electrode pattern of the light emitting device of each of the green sub-pixels, respectively.

13. The display substrate according to claim 1, wherein, for the sub-pixel opening and the first electrode pattern corresponding to each other, a shape of the sub-pixel opening is the same as a shape of the main part of the first electrode pattern,
a first orthographic projection of the sub-pixel opening on the base substrate is within a second orthographic projection of the main part of the first electrode pattern on the base substrate, and a minimum distance between an edge of the first orthographic projection and an edge of the second orthographic projection is from 1.5 micrometers to 3.5 micrometers.

14. The display substrate according to claim 7, wherein the light emitting devices of the red sub-pixels and the blue sub-pixels are located in same rows, the light emitting devices of the green sub-pixels of are substantially located in same rows, and the rows where the light emitting devices of the red sub-pixel and the blue sub-pixel are located and the rows where the light emitting devices of the green sub-pixels are located are arranged alternately.

15. The display substrate according to claim 1, wherein the drive circuit layer further comprises a plurality of second gaps, wherein the plurality of second gaps allow light from the display side to transmit therethrough,
in the direction perpendicular to the base substrate, the plurality of second gaps do not overlap with the plurality of first electrode patterns and the plurality of light-blocking patterns.

16. The display substrate according to claim 15, wherein a distance of the plurality of second gaps from a center of the plurality of sub-pixel openings is greater than 33 micrometers,
a width of each of at least a portion of the plurality of second gaps is greater than 4.0 micrometers.

17. The display substrate according to claim 15, wherein an orthographic projection of each of the plurality of second gaps on the base substrate is located between an orthographic projection of light emitting control signal line on the base substrate and an orthographic projection of a reset voltage line adjacent to the light emitting control signal line on the base substrate.

18. The display substrate according to claim 17, wherein an orthographic projection of each of at least a portion of the plurality of second gaps on the base substrate is located between an orthographic projection of a light emitting control signal line for a blue sub-pixel on the base substrate and an orthographic projection of a reset voltage line for a red sub-pixel on the base substrate, wherein the red sub-pixel is located in a row next to a row where the blue sub-pixel is located and is adjacent to the blue sub-pixel; and/or
an orthographic projection of each of at least a portion of the plurality of second gaps on the base substrate is located between an orthographic projection of a light emitting control signal line for a red sub-pixel on the base substrate and an orthographic projection of a reset voltage line for the blue sub-pixel on the base substrate, wherein the blue sub-pixel is located in a row next to a row where the red sub-pixel is located and is adjacent to the red sub-pixel.

19. (canceled)

20. The display substrate according to claim 1, wherein the drive circuit layer comprises,
a plurality of pixel drive circuits, and
a first planarization layer, disposed on a side of the plurality of pixel drive circuits away from the base substrate and comprising a plurality of firs via holes, wherein the plurality of first via holes expose output terminals of the plurality of pixel drive circuits, respectively,
wherein the first electrode layer is disposed on a side of the first planarization layer away from the base substrate, and the plurality of first electrode patterns are connected with the output terminals of the plurality of pixel drive circuits through the plurality of first via holes, respectively,
the display substrate further comprises a spacer layer disposed on a side of the pixel definition layer away from the base substrate, and the spacer layer comprises a plurality of spacers;
in the direction perpendicular to the base substrate, the plurality of spacers do not overlap with the plurality of first via holes.

21. (canceled)

22. The display substrate according to claim 1, wherein the drive circuit layer comprises,
a plurality of pixel drive circuits,
a first planarization layer, disposed on a side of the plurality of pixel drive circuits away from the base substrate and comprising a plurality of firs via holes, wherein the plurality of first via holes expose output terminals of the plurality of pixel drive circuits, respectively,
a connection electrode layer, disposed on a side of the first planarization layer away from the base substrate and comprising a plurality of connection electrodes, wherein the plurality of connection electrodes are electrically connected with the output terminals of the plurality of pixel drive circuits through the first via holes, respectively, and
a second planarization layer, disposed on a side of the connection electrode layer away from the base substrate and comprising a plurality of second via holes, wherein the plurality of second via holes expose the plurality of connection electrodes, respectively;
wherein the first electrode layer is disposed on a side of the second planarization layer away from the base substrate, and the plurality of first electrode patterns are electrically connected with the plurality of connection electrodes, respectively,
the display substrate further comprises a spacer layer disposed on a side of the pixel definition layer away from the base substrate, and the spacer layer comprises a plurality of spacers,
in the direction perpendicular to the base substrate, the plurality of spacers do not overlap with the plurality of second via holes.

23-26. (canceled)
